(19) United States
(12) Patent Application Publication
(10) Pub. No.: US 2006/0028800 A1
(43) Pub. Date: Feb. 9, 2006

(54) Condensation accumulation removal apparatus and method

(76) Inventors: Gregory M. Chrysler, Chandler, AZ (US); Ioan Sauciuc, Phoenix, AZ (US)

Correspondence Address: SCHWABE, WILLIAMSON & WYATT, PACWEST CENTER, SUITE 1900, 1211 S.W. FIFTH AVE., PORTLAND, OR, 97204, US

(21) Appl. No.: 10/910,825

(22) Filed: Aug. 3, 2004

(51) Int. Cl. H05K 7/20

(52) U.S. Cl. 361/700; 165/80.4; 165/104.33

(57) ABSTRACT

A condensate removal apparatus with a wick structure, method for condensate removal and system for condensate removal using such a wick structure are described herein.

### TECHNICAL FIELD & BACKGROUND

Embodiments of the present invention are related to the field of thermal management. In particular, embodiments of the present invention are related to removal of condensation produced from chilled air outputted by refrigerated cooling systems for cooling e.g. electronic packages or devices. When condensation accumulates in these devices, growth of molds, oxidation of materials and degradation of electronic performance and life may occur. Prior art removal efforts have been ad-hoc and not very effective.

### BRIEF DESCRIPTION OF THE DRAWINGS

Embodiments, of the present invention will be described by way of exemplary embodiments, but not limitations, illustrated in the accompanying drawings in which like references denote similar elements, and in which:

FIG. 1 illustrates a functional view of a condensation removal apparatus, in accordance with one embodiment; and

FIGS. 2 illustrate a functional view of a system having the condensation removal apparatus of FIG. 1 in accordance with one embodiment.

### DETAILED DESCRIPTION OF ILLUSTRATIVE EMBODIMENTS

Embodiments of the present invention include, but are not limited to, an apparatus for passively removing condensation accumulation comprising of a wicking material in fluidic contact with accumulated condensation exposed to a heated airflow evaporating the condensate, and method for removing the condensation.

Various aspects of the illustrative embodiments will be described using terms commonly employed by those skilled in the art to convey the substance of their work to others skilled in the art. However, it will be apparent to those skilled in the art that the alternate embodiments may be practiced with only some of the described aspects. For purposes of explanation, specific numbers, materials and configurations are set forth in order to provide a thorough understanding of the illustrative embodiments. However, it will be apparent to one skilled in the art that alternate embodiments may be practiced without the specific details. In other instances, well-known features are omitted or simplified in order not to obscure the illustrative embodiments.

Various operations will be described as multiple discrete operations, in turn, in a manner that is most helpful in understanding the present invention. However, the order of description should not be construed as to imply that these operations are necessarily order dependent. In particular, these operations need not be performed in the order of presentation.

The phrase “in one embodiment” is used repeatedly. The phrase generally does not refer to the same embodiment. However, it may. The terms “comprising”, “having” and “including” are synonymous, unless the context dictates otherwise.

By using low temperature (chilled or air conditioned) air, a central processing unit (CPU) junction temperature can be dropped further than when ambient air alone is used. Additionally, other non-CPU components can be cooled to lower temperatures. Depending on the air humidity some condensate may be generated during the refrigeration process. The condensate needs to be eliminated and removed from the chassis and/or the environment containing the CPU and non-CPU components. The embodiments shown by this invention comprises collecting the condensate in a condensate reservoir. A wick structure is in fluidic contact with the condensate in the reservoir. By absorbing the condensate and spreading it over a larger surface area, the wick structure may increase the exposure of the condensate to hot air produced by a heat outputting source, in this case, the CPU being cooled, prior to exiting the chassis/environment. As a result, the condensate will re-evaporate and will be carried back into the room or system. The apparatus is relatively simple and may be fabricated at relatively low cost.

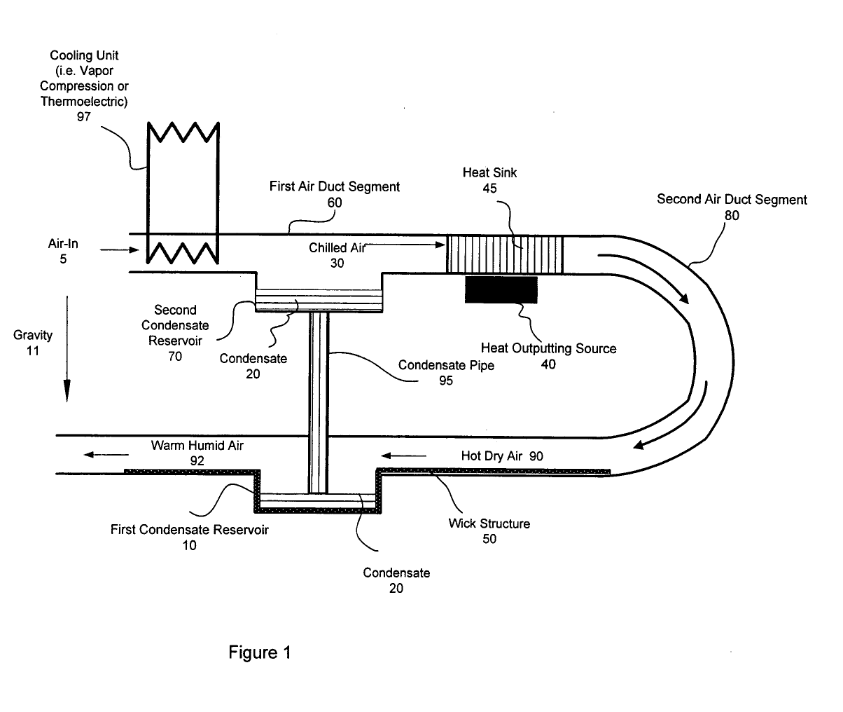

FIG. 1 shows a function view of a condensation removal apparatus 100 in accordance with one embodiment, is shown. As illustrated, for the embodiment, moisture in air-in 5 is condensed into a condensate 20 by chilling the air-in 5. The chilled air-in 5 becomes chilled air 30. A first condensate reservoir 10 is used to collect the condensate 20 from the chilled air 30 being routed to cool a heat outputting source 40. A wick structure 50 is in fluidic contact with the condensate collected in the first condensate reservoir 10. The wick structure 50 exposes the collected condensate 20 to hot dry air 90 being routed away from the heat outputting source 40. This exposure to the hot dry air 90 evaporates the collected condensate 20. The hot dry air 90 is the chilled air 30 after removing heat from the heat outputting source 40.

The chilled air 30 is routed over a first air path to the heat outputting source 40; for the illustrated embodiment, the first air path is framed by a first air duct segment 60. A second condensate reservoir 70 is disposed in the first air path 60 to collect the condensate 20 precipitating out of the chilled air 30 prior to the chilled air 30 reaching the heat outputting source 40. A second air path routes the hot dry air 90 away from the heat outputting source 40; for the illustrated embodiment, the second air path is framed by second air duct segment 80. However, neither the first air path, nor the second air path needs to be framed by solid air ducts. Rather, the first air path and the second air path may be merely a flow of air without ducting or just partially framed with ducting. To facilitate the removal of heat from the heat outputting source 40, a heat sink 45 or other heat transfer device may be thermally coupled to the heat outputting source 40 with air fins extending into the chilled air 30 being routed. The first condensate reservoir 10 is located in the second air duct segment 80. A fluid pipe segment 95 couples the first condensate reservoir 10 to the second condensate reservoir 70 allowing the condensate 20 collected in the second condensate reservoir 70 to be routed to the first condensate reservoir 10. For the illustrated embodiment, gravity 11 causes the condensate 20 to flow from the first condensate reservoir 10 to the second condensate reservoir 70 through the fluid pipe segment 95. However, other mechanisms may be employed to move the condensate 20 from the condensate reservoir 10 to the second condensate reservoir 70 through the fluid pipe segment 95 including pumping devices.

A further embodiment includes a cooling unit 97 coupled to the first air duct segment 60, thereby chilling air-in 5 to provide the chilled air 30. The cooling unit 97 may comprise a vapor compression cooling system or a thermoelectric cooling system. The apparatus may also comprise the heat outputting source 40 as described in an embodiment.

The wick structure 50 maybe selected from a group consisting of extruded groove wicks, mesh screen wicks, sintered powders wicks, graded wicks and combinations of the same.

Referring once more to FIG. 1, one embodiment entails a method collecting condensate 20 created by the chilled air 30 used to cool the heat outputting source 40 and eliminate the condensate 20 by evaporation. The condensate 20 is collected in a wick structure 50, and then by exposing a portion of the wick structure 50 to hot dry air 90 routed away from the heat outputting source 40, the condensate 20 is evaporated. The hot dry air 90 is the chilled air 30 after removing heat from the heat outputting source 40.

The method further includes routing the chilled air 30 to the heat outputting source 40. Moisture in the chilled air 30 being routed becomes the condensate 20. The collecting of the condensate 20 comprises collecting the condensate 20 in a second condensate reservoir 70; and routing the collected condensate 20 to a first condensate reservoir 10 to be in fluidic contact with the wick structure 50. While the wick structure 50 collects and distributes the condensate 20 throughout itself, hot dry air 90 is routed from the heat outputting source 40 to the wick structure 50. The hot dry air 90 in contact with the wick structure 50 evaporates the condensate 20 contained within the wick structure 50 thereby reducing the temperature of the hot dry air 90 while increasing the relative humidity creating warm humid air 92. Warm humid air 92 created by the evaporation is then vented away from the apparatus thereby removing the condensate 20.

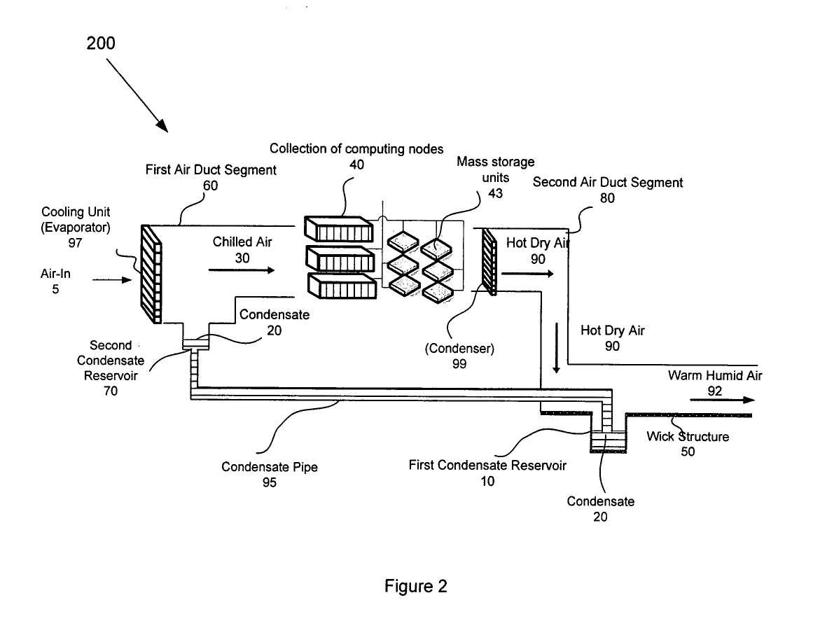

FIG. 2 illustrates a system 200 in accordance with one embodiment. As illustrated, for the embodiment, system 200 includes a collection of one or more electronic devices 40 and one or more mass storage units 43 for storing data. The electronic devices 40 output heat during operation. Condenser 99 also outputs heat during operation. Chilled air 30 is routed to cool the electronic devices 40 during its operation. At the same time, the chilled air becomes heated by the electronic devices 40. The chilled air becomes further heated as it is routed through the condenser 99 at the same time cooling the condenser 99 creating hot dry air 90. Condensate 20 precipitating out of the chilled air 30 as it is being routed is collected in a first condensate reservoir 10. A wick structure 50 in fluidic contact with the first condensate reservoir 10 is used to expose the collected condensate 20 to hot dry air 90 routed away from the electronic devices 40 and from the condenser 99. This exposure to the hot dry air 90 evaporates the collected condensate 20 thereby reducing the temperature of the hot dry air 90 while increasing the relative humidity creating warm humid air 92. The warm humid air 92 is then vented out of the system thereby removing the condensate 20 from the system 200.

In this embodiment, the one or more electronic devices 40 comprise a collection of computer nodes. Additionally, the system further comprises a cooling unit 97 to provide the chilled air 30, a first air duct segment 60 coupling the chilled air 30 from the cooling unit 30 to the collection of electronic devices/computer nodes 40, and a second air duct segment 80 coupling the hot dry air 90 from the collection of electronic devices/computer nodes 40 to the wick structure 50. A second condensation reservoir 70 is disposed within the first air duct segment 60 and the first condensation reservoir 10 is disposed within the second duct segment 80. A fluid pipe 95 is used to couple the condensate 20 collected in the second condensate reservoir 70 to the first condensate reservoir 10. The wick structure 50 is selected from group consisting of extruded groove wicks, mesh screen wicks, sintered powders wicks, graded wicks, and combinations of the same.

Depending on the applications, system 200 may include other electrical devices, including but are not limited to a multi-processor system, a cluster of (blade) servers, a massively parallel computing system, a supercomputing system, or other devices of the like.

Thus, it can be seen from the above descriptions, a novel apparatus using wicking structures and heated air for removal of condensation, and method for removal of condensation using such wicking structures and heated air have been described. While embodiments of the present invention have been described in terms of the foregoing embodiments, those skilled in the art will recognize that embodiments of the present invention are not limited to the embodiments described. The present embodiments of this invention can be practiced with modification and alteration within the spirit and scope of the appended claims.

Therefore, the description is to be regarded as illustrative instead of restrictive.

What is claimed is:

1. An apparatus comprising:
a first condensate reservoir to collect condensate from chilled air being routed to cool a heat outputting source; and
a wick structure in fluidic contact with the condensate collected in the first condensate reservoir to expose the collected condensate to hot dry air being routed away from the heat outputting source, to evaporate the collected condensate, the hot air being the chilled air after removing heat from the heat outputting source.

2. The apparatus of claim 1, wherein the apparatus further comprises:
a first air duct segment to route the chilled air to the heat outputting source;
a second condensate reservoir disposed within the first air duct segment to collect the condensate from the chilled air;
a second air duct segment to route the hot dry air away from the heat outputting source, the first condensate reservoir being disposed in the second air duct segment; and
a fluid pipe segment coupling the condensate collected in the second condensate reservoir to the first condensate reservoir.

3. The apparatus of claim 2, wherein the apparatus further comprises a cooling unit coupled to the first air duct segment to provide the chilled air to the heat outputting source.

4. The apparatus of claim 1, wherein the apparatus further comprises a first air duct segment to provide the chilled air to the heat outputting source; and a cooling unit coupled to the first air duct segment to provide the chilled air to the first air duct segment.

5. The apparatus of claim 1, wherein the apparatus further comprises the heat outputting source.

6. The apparatus of claim 1, wherein the wick structure is selected from a group consisting of extruded groove wicks, mesh screen wicks, sintered powders wicks, graded wicks, and combinations of the same.

7. A method comprising:
collecting condensate created by chilled air being routed to cool a heat outputting source in a wick structure; and
exposing the wick structure to hot dry air being routed away from the heat outputting source, to evaporate the collected condensate, the hot dry air being the chilled air after removing heat from the heat outputting source.

8. The method of claim 7, wherein the method further comprises routing the chilled air to the heat outputting source.

9. The method of claim 7, wherein the collecting comprises collecting the condensate in a second condensate reservoir; and routing the collected condensate to a first condensate reservoir in fluidic contact with the wick structure.

10. The method of claim 7, wherein the method further comprises routing the hot dry air from the heat outputting source to the wick structure.

11. A system comprising:
one or more mass storage units;
an electronic device coupled to the one or more mass storage units, the electronic device outputting heat during operation;
a first condensate reservoir adapted to collect condensate created by chilled air being routed to cool the electronic device during its operation; and
a wick structure in fluidic contact with the first condensate reservoir to expose the collected condensate to hot dry air being routed away from the electronic device, to evaporate the collected condensate, the hot dry air being the chilled air after removing heat from the electronic device.

12. The system of claim 11, wherein the electronic device comprises a collection of computing nodes.

13. The system of claim 11, wherein the system further comprises;
a cooling unit to provide said chilled air; and
a first air duct segment coupling the chilled air from the cooling unit to the electronic device, the second condensation reservoir being disposed within the first air duct segment.

14. The system of claim 13, wherein the cooling unit further comprises;
a condenser outputting heat; and
the first air duct segment coupling the hot dry air from the electronic device to the condenser.

15. The system of claim 13, wherein the system further comprises:
a second air duct segment coupling the hot air from the electronic device to the wick structure;
a first condensate reservoir disposed inside the second air duct segment, the wick structure being in fluidic contact with the first condensate reservoir; and
a fluid pipe segment coupling the condensate from the second condensate reservoir to the first condensate reservoir.

16. The system of claim 14, wherein the system further comprises:
a second air duct segment coupling the hot air from the condenser to the wick structure;
a first condensate reservoir disposed inside the second air duct segment, the wick structure being in fluidic contact with the first condensate reservoir; and
a fluid pipe segment coupling the condensate from the second condensate reservoir to the first condensate reservoir.

17. The system of claim 11, wherein the wick structure is selected from a group consisting of extruded groove wicks, mesh screen wicks, sintered powders wicks, graded wicks, and combinations of the same.
